(19) United States
(12) Patent Application Publication
(10) Pub. No.: US 2008/0150080 A1
(43) Pub. Date: Jun. 26, 2008

(54) Protective Diode for Protecting Semiconductor Switching Circuits from Electrostatic Discharges

(75) Inventors: Steffen Thiem, Moritzburg (DE); Steffen Buschbeck, Dresden (DE)

Correspondence Address: HESLIN ROTHENBERG FARLEY & MESITI PC, 5 COLUMBIA CIRCLE, ALBANY, NY, 12203, US

(73) Assignee: ZENTRUM MIKROELEKTRONIK, Dresden (DE)

(21) Appl. No.: 10/598,205

(22) PCT Filed: Feb. 16, 2005
(86) PCT No.: PCT/DE2005/000268

§ 371 Date: Sep. 11, 2007

(30) Foreign Application Priority Data
Feb. 20, 2004 (DE) 10 2004 008 803.9

(51) Int. Cl. H01L 23/62

(52) U.S. Cl. 257/546; 257/E23.001

(57) ABSTRACT

The invention relates to an arrangement of a protective diode for protecting semiconductor switching circuits from electrostatic discharges. The aim of the invention is to create an arrangement by which means improved ESD protection with optimum chip surface use and an improved latch-up behaviour can be achieved. To this end, the planar diode consists of a first insular electrode surrounded by a second electrode, the contacts of the first electrode being contacted by a first metallic plane, and the contacts of the second electrode by a second, superimposed metallic plane.

The invention relates to a system for protecting semiconductor circuits from electrostatic discharges, comprising a planar diode (having two electrodes) which are respectively contacted by a plurality of contacts, and the contacts are connected by means of metallic layers to the operating voltage, to an input/output pad, or to ground.

In the manufacturing process as well as during subsequent installation in a higher-level circuit system and operation of the integrated circuit, this circuit is exposed to unavoidable environmental influences, including, for example, electrostatic discharges (ESD).

Electrostatic charges arise due to friction between various materials, and may generate voltages of several kV on a charge carrier. When the charge carrier is contacted, for example by a pin in the integrated component, the stored charge discharges in the nanosecond range and temporarily generates currents in the ampere range. This current must be discharged through the ESD protective circuit and the corresponding printed conductors. The design of this conducting path limits the ESD protection in such a way that exceedance of an allowable current density at the time of discharge causes the destruction of parts of the integrated circuit due to thermal overload. Since the current densities in the ESD discharge increase with smaller structural dimensions, the ESD problem assumes greater importance as the integration density of the integrated circuits increases.

One measure known from the prior art for protecting against electrostatic discharges is the connection of protective diodes between the input/output pad and the VDD voltage as well as the VSS ground. The connection is made in such a way that the first protective diode is connected to the cathode at the VDD voltage and to the anode at the input/output pad, and the second protective diode is connected to the cathode at the input/output pad and to the anode at the VSS voltage.

Various test standards for compliance with quality requirements exist for current ICs. The human body model (HBM) test method presently in use is increasingly becoming replaced by the charge device model (CDM) test method. The CDM test method imposes increased demands on the current-carrying capacity of the ESD protective elements. The current load is approximately 10 times greater than in the HBM test. Since the time span for the current pulse in the CDM test is less than 1 ns, in practical terms adiabatic heating occurs as a result of the current flow. Thus, for current discharge in a CDM test method with 1 kV high-voltage discharge, significantly more chip surface is required than in an HBM test method with 4 kV. Due to this increased demand for chip surface, a portion of the chip surface gained from structural miniaturization is lost. In a CDM test method the discharge current intensity greatly increases through a protective diode, resulting in an enlargement of the diode surface.

As the current intensity and structural miniaturization increase, which results in a higher integration density, the latch-up characteristics of the system become more and more critical. As a result of the large cathode surface, which for example is surrounded by an anode ring, a substrate current is generated which penetrates deeply into the substrate and which therefore cannot be completely absorbed by the anode. This current may then cause a malfunction in adjacent integrated structures.

A system of a protective diode is known from U.S. Pat. No. 5,594,266 for protecting semiconductor circuits from electrostatic discharges, the system comprising a planar diode having two electrodes which are each contacted by contacts, and the contacts are connected by means of metallic planes to the operating voltage, to a pad, or to ground. The planar diode is composed of a first insular electrode surrounded by a second electrode, the contacts of the first electrode being contacted by a first metallic plane, and the contacts of the second electrode being contacted by a second metallic plane.

The disadvantage of this system is that a larger chip surface for the diode is required as a result of the high demands on the protective diode (current load). As the current intensity and structural miniaturization increase, which results in a higher integration density, the latch-up characteristics of the system become more and more critical. As a result of the large cathode surface, which for example is surrounded by an anode ring, a substrate current is generated which penetrates deeply into the substrate and which therefore cannot be completely absorbed by the anode. This current may then cause a malfunction in adjacent integrated structures.

A protective diode is known from U.S. Pat. No. 6,518,604 having elongated anode and cathode stripes. This system ensures that the current generated in the substrate is drawn off to the surface and is not able to penetrate deeply into the substrate. For this type of diode, the current flow through the edge of the diode is greater than the current through the base area.

The disadvantage of this system is the increased space requirement, since the division into diode fingers as a result of the necessary distance between anode and cathode contact areas requires additional chip surface. In addition, the edge pieces of the diode fingers are not used for the dissipation of current. For long fingers, the dimensions of the metal lines for the individual anode and cathode lines must be adapted to the current density. This adaptation requires additional space while observing design specifications.

A semiconductor diode is known from DE 197 46 620 having two electrodes, which form the cathode and anode, at least one of the electrodes being curved, and the surface of the other electrode occupying a maximum 20% of the product of the width of the other electrode and the inner edge length of the curved electrode.

A method for manufacturing a substrate is known from US 2002/0088978 containing active elements arranged in rows and columns. Each individual element is connected to a TFT transistor having a gate electrode connected to the associated row line, and having source and drain connections, which are connected to the corresponding row line. An ESD protective circuit is connected to at least one row line for protecting the TFT transistor from electrostatic charge.

The object of the present invention, therefore, is to provide a system of a protective diode for protecting semiconductor circuits from electrostatic discharges, resulting in improved ESD protection with optimum use of the chip surface and improved latch-up characteristics.

According to the invention, the object is achieved by a system of a protective diode of the aforementioned type for protecting semiconductor circuits from electrostatic discharges in that a plurality of planar diodes is provided in a common first electrode, each planar diode having a second insular electrode surrounded by the first electrode, and the contacts of the electrode are contacted by a first metallic plane and the contacts of the electrode are contacted by a superposed second metallic plane.

Diodes are implemented on wafers preferably in the form of a planar diode having a large surface cross section for the pn transition. According to the approach of the invention, a first electrode is embedded in the surface of the second electrode, the insular first electrode having, for example, a circular or rectangular shape. Each electrode is connected in an electrically conductive manner to various superposed metallic planes by means of a plurality of contacts. The use of a plurality of electrically conductive contacts connected in parallel balances out fluctuations in resistance of the individual contacts and reduces the current density in the lead.

One embodiment of the invention provides that multiple planar diodes are situated adjacent to one another.

In a further embodiment of the invention, multiple planar diodes are situated in an array.

This system of multiple cathode islands, for example, in a common anode surface may be achieved in a row, a column, a combination of rows and columns, or in the form of an array.

In one special embodiment of the invention, the planar diodes are interconnected to form a functional unit.

The planar diodes are preferably connected in parallel to a protective diode, which is dimensioned for a current load required for reliable ESD protection. The protective diode produced in this manner may also be composed of multiple interconnected rows and/or columns of planar diodes, or multiple arrays.

Due to technological requirements, a plurality of contacts is used for contacting the electrodes. Taking into consideration the line resistance and current load capacity of the contact, with appropriate dimensioning it is possible to use only one contact for connecting an electrode to a metallic plane.

In one embodiment of the invention, the insular electrode has a circular or polygonal shape.

The shape of the insular electrode may be adapted, for example, to a manufacturing technology that is employed. The electrode may have either a circular or polygonal shape, with any given number of corners.

The invention is explained in greater detail below, with reference to one exemplary embodiment. The associated drawings show the following:

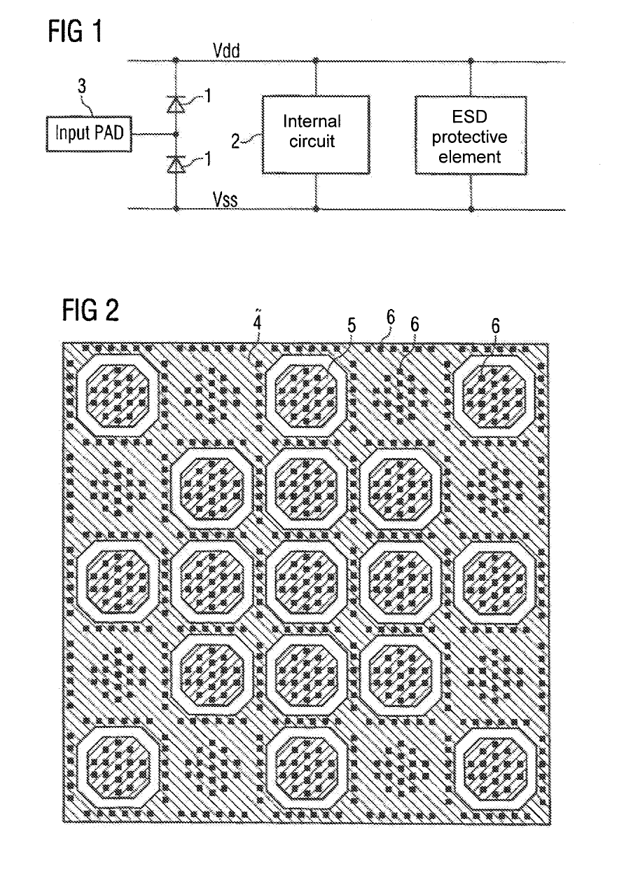

FIG. 1 shows an ESD protective circuit having two protective diodes from the prior art;

FIG. 2 shows an illustration of the lowest layout plane of the protective diode according to the invention;

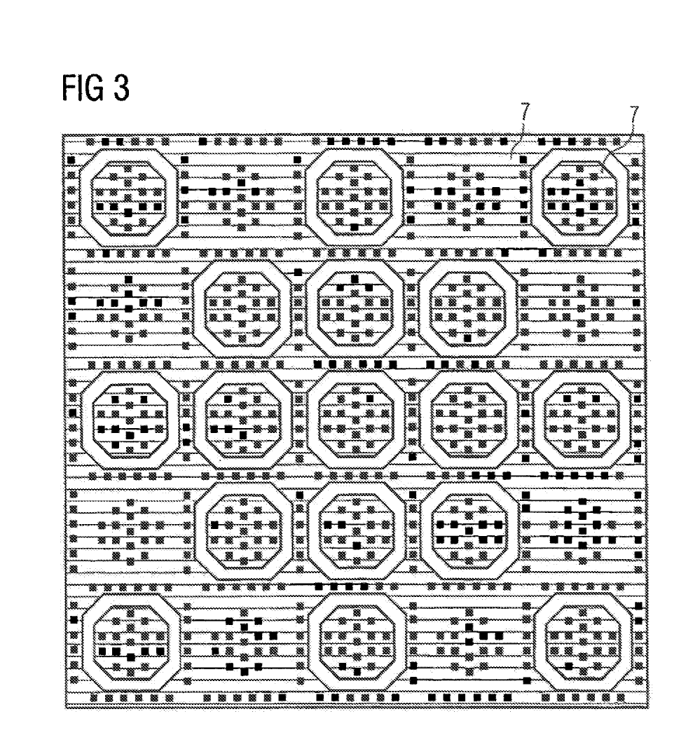

FIG. 3 shows an illustration of the connection of the anode and cathode surfaces to the superposed metallic plane;

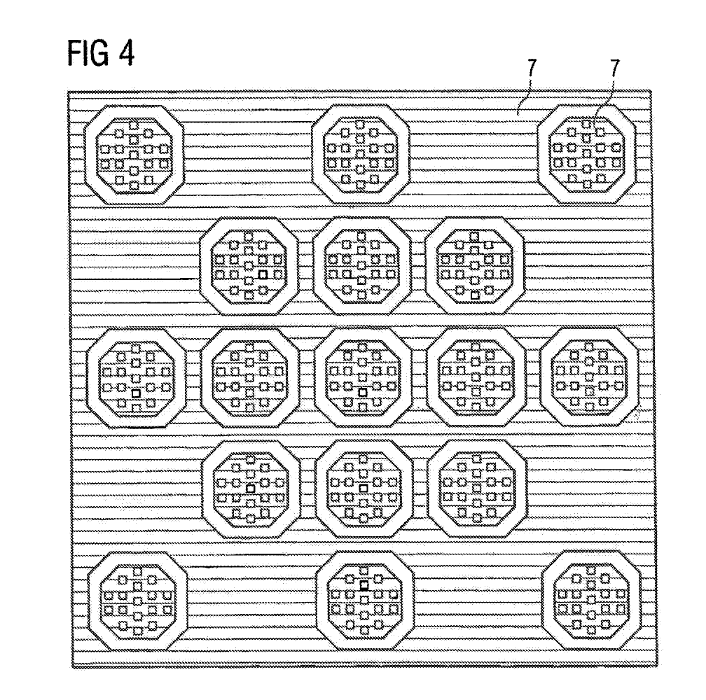

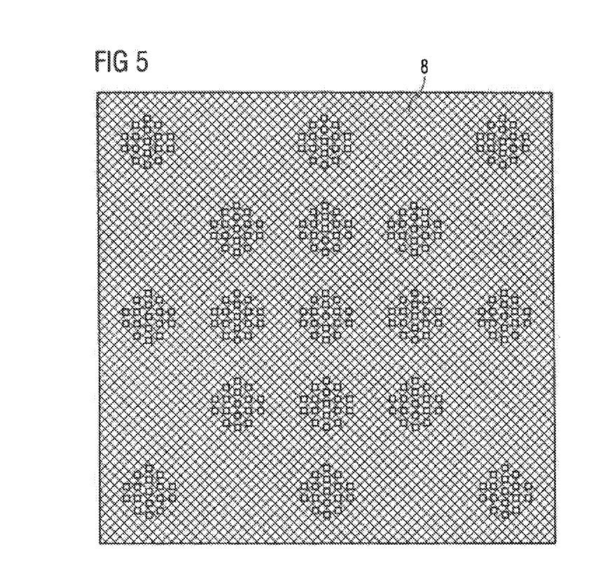

FIG. 4 shows an illustration of the first metallic plane with via contacts; and

FIG. 5 shows an illustration of the second metallic plane with via contacts.

FIG. 1 illustrates an ESD protective circuit having two protective diodes 1 from the prior art. In this system, the internal circuit 2 is protected from electrostatic discharges at one of the input pads 3. The approach of the invention may find application in both protective diodes 1.

A diode design for a diode that is embodied as a planar diode and improved for surface optimization is obtained not by dividing the diode into anode and cathode stripes, but, rather, by using an anode surface 4 with a cathode island 5 embedded therein. A configuration of the planar diode having an anode island in a cathode surface is also possible. By use of this approach, the surface of the cathode island 5, the anode surface 4, the edge of the cathode island 5, and the number of contacts 6 may be optimally matched to one another in the cathode island 5 as well as in the anode surface 4 and the metallic track width in such a way that when multiple planar diodes are interconnected to form one protective diode 1 each planar diode element withstands the same current load. As a result of the selection options for the shape and size of the island 5, a surface-optimized design may be found. Subdivision of the protective diode 1 into partial-surface diodes prevents significant substrate current to adjacent chip elements. Depending on the available space in the layout, the structure of the protective diode 1 composed of multiple planar diodes may be square or rectangular, or may be divided into multiple substructures.

According to the approach of the invention, the cathode island 5 is designed with an octagonal shape having angles of 45 degrees each. Another geometric shape such as a circle or square is also possible. To ensure a uniformly distributed current flow through all islands 5, the size, geometric shape, embedding, and contacting 6 of the islands 5 are designed in the same way. To balance fluctuations in resistance of the contacts 6, ten contacts 6, for example, per island 5 are used. The current supply to the islands 5 is provided by contacts 6 to a superposed metallic plate, which likewise is insular, in the first metallic plane 7, and subsequently by means of vias to a superposed second metallic plane 8 in which the partial currents of the islands 5 are combined. This ensures that the total conducting-state current is uniformly distributed over all islands 5 connected in parallel. Since the second metallic plane 8 extends in a large area over the entire diode surface, the current density in this metallic plane 8 does not represent a limitation for the possible current through the diodes. The electrode surface 4 in which the islands 5 are embedded fills the areas between the islands 5 while complying with minimum design specifications. Thus, for example, the anode surface 4 must be at least as large as the sum of the cathode island surfaces to prevent substrate currents from appearing on other chip elements. Furthermore, the distribution of the cathode islands 5 must decrease along the edge of the anode surface 4 in order to keep the current density approximately constant in the first metallic plane 7, which represents the anode lead. The anode surface 4 is likewise attached by means of contacts 6 to the first metallic plane 7, an overlap of the metallic plane 7 with the outer sides being necessary, thus enabling a four-sided connection of the anode surface 4 to an associated line by means of the first metallic plane 7.

FIGS. 2 through 5 illustrate implementation of the system according to the invention in various superposed layout planes. The lowest plane is illustrated in FIG. 2. In this plane, the cathode islands 5 and the anode surface 4 are illustrated in a silicon substrate. Both the cathode islands 5 and the anode surface 4 are provided with contact plugs 6 for the connection to the first metallic plane 7.

FIG. 3 illustrates the connection of the cathode islands 5 and the anode surface 4 to the first metallic plane 7 superposed thereto. All anode connections are guided onto a common metallic plate in the first metallic plane 7, which then is connected to all side edges, for example, to the GND bus. By means of the islands 5 the metallic surfaces are insulated in the first metallic plane 7 as well as with respect to one another and with respect to the remaining metallic surface on the same plane, and by means of contacts 6 from the first metallic plane 7 are upwardly connected to the second metallic plane 8 superposed thereto. Such contacts 6 are also referred to as vias.

FIG. 4 illustrates the first metallic plane 7 with the via contacts. These via contacts are then connected to the second metallic plane 8.

FIG. 5 illustrates the second metallic plane 8 with the connected via contacts. This metallic plane 8 is dimensioned large enough so that it does not experience any damage after a current load resulting from an electrostatic discharge. The attachment, for example to an input pad, is made by means of this metallic plane 8.

### LIST OF REFERENCE NUMERALS

1 Protective diode
2 Internal circuit
3 Input pad
4 Anode surface
5 Cathode island
6 Contact
7 First metallic plane
8 Second metallic plane

1. Protective diode system for protecting semiconductor circuits from electrostatic discharges, comprising at least one planar diode having two electrodes which are respectively contacted by a plurality of contacts, and the contacts are connected by means of metallic planes to the operating voltage, to a pad, or to ground, characterized in that the planar diode comprises a first insular electrode (5) enclosed by a second electrode (4), and the contacts (6) of the first electrode (5) are contacted by a first metallic plane (7), and the contacts (6) of the second electrode (4) are contacted by a superposed second metallic plane (8).

2. System according to claim 1, characterized in that multiple planar diodes are situated adjacent to one another.

3. System according to claim 1, characterized in that multiple planar diodes are situated in an array.

4. System according to claim 2 and 3, characterized in that the planar diodes are interconnected to form a functional unit.

5. System according to claim 1, characterized in that the plurality of contacts (6) is replaced by a single contact.

6. System according to claim 1, characterized in that the insular electrode (5) has an n-angular shape.
